(19) United States
(12) Patent Application Publication
(10) Pub. No.: US 2005/0263858 A1
(43) Pub. Date: Dec. 1, 2005

(54) Semiconductor device

(76) Inventors: Ryota Katsumata, Yokohama-shi (JP); Hideaki Aochi, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/947,390

(22) Filed: Sep. 23, 2004

(30) Foreign Application Priority Data
May 26, 2004 (JP) 2004-156071

(51) Int. Cl. H01L 23/58

(52) U.S. Cl. 257/649

(57) ABSTRACT

A semiconductor device includes an upper electrode, a lower electrode, a capacitor insulating film formed between the upper and lower electrodes, and containing aluminum, a first nitrogen-containing film formed between the capacitor insulating film and upper electrode, and containing nitrogen, and a second nitrogen-containing film formed between the capacitor insulating film and lower electrode, and containing nitrogen, wherein at least one of the first and second nitrogen-containing films contains not less than 1% of nitrogen.

### CROSS-REFERENCE TO RELATED APPLICATIONS

This application is based upon and claims the benefit of priority from prior Japanese Patent Application No. 2004-156071, filed May 26, 2004, the entire contents of which are incorporated herein by reference.

### BACKGROUND OF THE INVENTION

1. Field of the Invention

The present invention relates to a semiconductor device including a capacitor having a capacitor insulating film containing aluminum.

2. Description of the Related Art

Recently, as the chip size of a DRAM (Dynamic Random Access Memory) decreases, the area of a capacitor for storing electric charge also decreases, and this makes it difficult to obtain a sufficient capacitance. In a DRAM, data is stored by storing electric charge in a capacitor. To obtain good data holding characteristics, it is important to increase the capacitance of the capacitor, reduce a leakage current, and increase a write electric current to the capacitor.

For this purpose, many devices have been studied to change a dielectric film forming the capacitor from an NO (Nitride Oxide) film, which is presently most frequently used, to another high dielectric film. This is so because this high dielectric film makes it possible to obtain a larger capacitance, for the same physical film thickness, without increasing the leakage current. As an example, an Al₂O₃ film is a promising candidate for the high dielectric film.

On the other hand, many annealing steps are used in the fabrication of a DRAM since it is important to reduce the leakage current. This is so because a high-temperature heating step reduces point defects and alleviates the stress accumulated in a substrate, and this presumably reduces the leakage current. Accordingly, it is very important for the physical characteristics of a capacitor insulating film to remain stable, even after this high-temperature heating step.

Unfortunately, a capacitor using an Al₂O₃ single-layered film as a capacitor insulating film poses the following problem after the high-temperature heating step described above. That is, SIMS analyses as shown in FIGS. 15A and 16A revealed that the Al in Al₂O₃ films diffused in the node electrode and plate electrode (FIGS. 15B and 16B).

When Al as a p-type dopant diffuses in the node electrode and plate electrode as described above, the depletion ratios of these electrodes lower. As a consequence, the capacitance of the capacitor lowers.

The prior art references related to the invention of this application are as follows.

[Patent reference 1] U.S. Pat. No. 6,355,519

[Patent reference 2] U.S. Pat. No. 6,664,583

### BRIEF SUMMARY OF THE INVENTION

A semiconductor device according to a first aspect of the present invention comprises an upper electrode, a lower electrode, a capacitor insulating film formed between the upper and lower electrodes, and containing aluminum, a first nitrogen-containing film formed between the capacitor insulating film and upper electrode, and containing nitrogen, and a second nitrogen-containing film formed between the capacitor insulating film and lower electrode, and containing nitrogen, wherein at least one of the first and second nitrogen-containing films contains 1% or more of nitrogen.

A semiconductor device according to a second aspect of the present invention comprises an upper electrode, a lower electrode, and a capacitor insulating film formed between the upper and lower electrodes, containing aluminum, and having a first surface facing the upper electrode and a second surface facing the lower electrode, wherein at least one of the first and second surfaces of the capacitor insulating film contains 1% or more of nitrogen.

### BRIEF DESCRIPTION OF THE SEVERAL VIEWS OF THE DRAWING

FIG. 1 is a sectional view showing a semiconductor device having a trench capacitor according to the first embodiment of the present invention;

FIG. 2 is a graph showing the relationship between the film thicknesses of an Al₂O₃ film and SiN film forming the capacitor according to the first embodiment of the present invention and the depletion ratio of the capacitor;

FIGS. 3 to 5 are sectional views showing the steps of fabricating the semiconductor device having the trench capacitor according to the first embodiment of the present invention;

FIG. 6 is a graph showing the effect of suppressing diffusion of Al toward the node electrode in the semiconductor device having the trench capacitor according to the first embodiment of the present invention;

FIG. 7 is a graph showing the effect of increasing the depletion ratios of the node electrode and plate electrode in the semiconductor device having the trench capacitor according to the first embodiment of the present invention;

FIG. 8 is a sectional view showing a semiconductor device having a stacked capacitor according to the first embodiment of the present invention;

FIG. 9 is a sectional view showing a semiconductor device having a trench capacitor according to the second embodiment of the present invention, in which nitrogen is contained in an interface F1 between an Al₂O₃ film and plate electrode;

FIG. 10 is a sectional view showing a semiconductor device having a trench capacitor according to the second embodiment of the present invention, in which nitrogen is contained in an interface F2 between an Al₂O₃ film and node electrode;

FIG. 11 is a sectional view showing a semiconductor device having a trench capacitor according to the second embodiment of the present invention, in which nitrogen is contained in an interface F1 between an Al₂O₃ film and plate electrode, and in an interface F2 between an Al₂O₃ film and node electrode;

FIG. 12 is a sectional view showing a semiconductor device having a stacked capacitor according to the second embodiment of the present invention, in which nitrogen is contained in an interface F1 between an Al₂O₃ film and plate electrode;

FIG. 13 is a sectional view showing a semiconductor device having a stacked capacitor according to the second embodiment of the present invention, in which nitrogen is contained in an interface F2 between an Al₂O₃ film and node electrode;

FIG. 14 is a sectional view showing a semiconductor device having a stacked capacitor according to the second embodiment of the present invention, in which nitrogen is contained in an interface F1 between an Al₂O₃ film and plate electrode, and in an interface F2 between an Al₂O₃ film and node electrode;

FIG. 15A is a view showing SIMS analysis of a capacitor performed by the prior art;

FIG. 15B is a graph showing the way Al diffused toward the node electrode observed by the SIMS analysis shown in FIG. 15A;

FIG. 16A is a view showing SIMS analysis of a capacitor performed by the prior art; and

FIG. 16B is a graph showing the way Al diffused toward the plate electrode observed by the SIMS analysis shown in FIG. 16A.

### DETAILED DESCRIPTION OF THE INVENTION

Embodiments of the present invention will be described below with reference to the accompanying drawing. In the following explanation, the same reference numerals denote the same parts throughout the drawing.

### First Embodiment

In the first embodiment, an Al₂O₃ (alumina) film is used as a capacitor insulating film for a storage node, and sandwiched between films containing N (nitrogen).

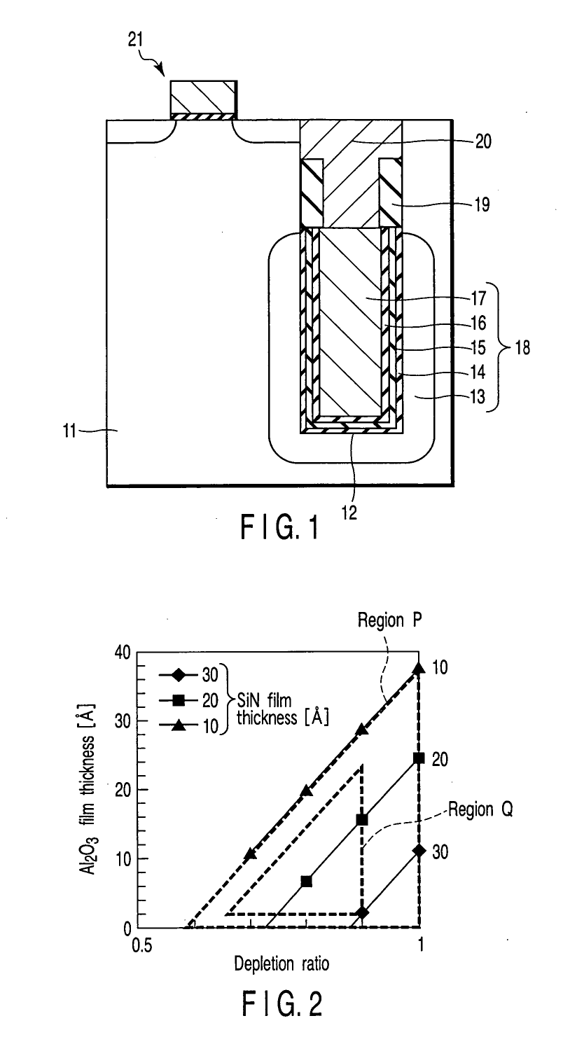

FIG. 1 is a sectional view of a semiconductor device having a trench capacitor according to the first embodiment of the present invention. The structure of this semiconductor device according to the first embodiment will be described below.

As shown in FIG. 1, in a memory cell of a DRAM, a trench 12 is formed in a silicon substrate (semiconductor substrate), and a trench capacitor 18 is formed in the trench 12. A transistor 21 is formed on the silicon substrate 11, and electrically connected to the capacitor 18 via a connecting portion 20.

The capacitor 18 consists of a plate electrode (lower electrode) 13 formed by doping the silicon substrate 11 with, e.g., an N-type impurity, a node electrode (upper electrode) 17 which is a polysilicon film containing, e.g., As, an Al₂O₃ film (capacitor insulating film) 15 formed between the plate electrode 13 and node electrode 17, a chemical oxide film (to be referred to as an oxynitride film hereinafter) 14 formed between the plate electrode 13 and Al₂O₃ film 15 and containing nitrogen, and an SiN film (silicon nitride film) 16 formed between the node electrode 17 and Al₂O₃ film 15.

The content of nitrogen in the oxynitride film 14 may be increased near the interface with the plate electrode 13 by nitriding in an ammonia ambient, or increased near the interface with the Al₂O₃ film 15 by plasma nitriding.

The content of nitrogen in the oxynitride film 14 is desirably about 1% or more.

A capacitor insulating film is not limited to the Al₂O₃ film 15, but may be any high dielectric film containing aluminum.

Also, films sandwiching the Al₂O₃ film 15 are not limited to the oxynitride film 14 and SiN film 16, but may be any films containing nitrogen (the content in each film is, e.g., 1% or more). For example, the film denoted by reference numeral “14” may be an SiN film, and the film denoted by reference numeral “16” may be an oxynitride film.

FIG. 2 shows the relationship between the film thicknesses of the Al₂O₃ film and SiN film forming the capacitor according to the first embodiment of the present invention, and the depletion ratio of the capacitor. The Al₂O₃ and SiN film thicknesses taking the depletion ratio of the capacitor into consideration will be explained below. Note that the depletion ratio of the capacitor may be measured from the capacitance and the film thickness of the entire capacitor.

As shown in FIG. 2, the relationship with the depletion ratio of the capacitor 18 indicates that the Al₂O₃ film 15 and SiN film 16 forming the capacitor 18 desirably have film thicknesses in a region P, and most desirably have film thicknesses in a region Q.

That is, in the region P, a film thickness X of the Al₂O₃ film 15 satisfies a relationship indicated by inequality (1) below, and a film thickness Y of the SiN film 16 satisfies a relationship indicated by inequality (2) below. In this state, the depletion ratio of the capacitor 18 may be about 0.6 to 1.0.
0<X<40 Å (1)
10 Å<Y<40 Å (2)

In the most desirable region Q, the film thickness X of the Al₂O₃ film 15 satisfies a relationship indicated by inequality (3) below, and the film thickness Y of the SiN film 16 satisfies a relationship indicated by inequality (4) below. In this state, the depletion ratio of the capacitor 18 may be about 0.65 to 0.9.
1 Å≦X≦25 Å (3)
15 Å≦Y≦30 Å (4)

The Al in the Al₂O₃ film 15 reacts with polysilicon forming the node electrode 17 more easily than the plate electrode 13 made of a diffusion layer. Therefore, the film thickness Y of the SiN film 16 is desirably larger than the film thickness X of the Al₂O₃ film 15. In addition, a film thickness Z of the oxynitride film 14 may be smaller than the film thickness X of the Al₂O₃ film 15 or the film thickness Y of the SiN film 16, e.g., 15 Å or less.

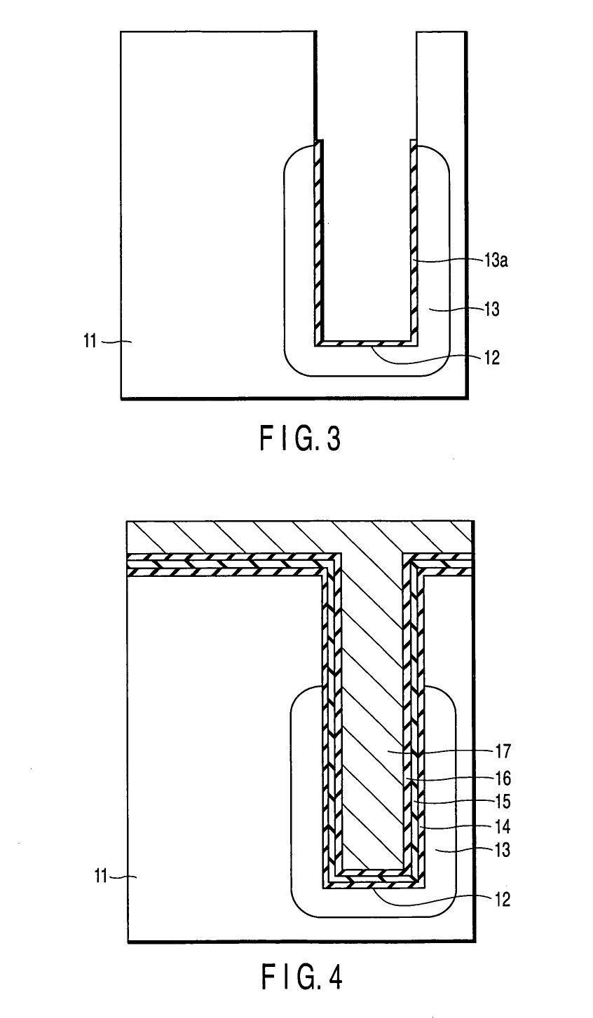

FIGS. 3 to 5 are sectional views showing the steps of fabricating the semiconductor device according to the first embodiment of the present invention. The method of fabricating the semiconductor device according to the first embodiment will be described below.

First, as shown in FIG. 3, a trench pattern is formed on a silicon substrate 11 by lithography, and a trench 12 is formed in the silicon substrate 11 by RIE (Reactive Ion Etching). Then, an AsSG (Arsenic Silicate Glass) film 13a about 200 Å thick is deposited on the silicon substrate 11 and in the trench 12, and the AsSG film 13a in the upper portion of the trench 12 is peeled off by a resist recess method. After a cap material film (not shown) such as a TEOS (Tetraethoxysilane Silicate) film is formed, high-temperature annealing at about 1,000° C. is performed. By this annealing, the As in the AsSG film 13a diffuses into the silicon substrate 11 outside the trench 12. Consequently, a plate electrode 13 made of the diffusion layer is formed along the outer side surfaces and outer bottom surface of the trench 12. After that, the AsSG film 13a is removed.

As shown in FIG. 4, after preprocessing is performed, a chemical oxide film formed on the silicon surface is nitrided as it is exposed to a nitrogen-containing reaction gas such as N₂O, NO, or NH₃. As a consequence, an oxynitride film 14 containing a large amount of nitrogen in the interface with the plate electrode 13 is formed on the inner side surfaces and inner bottom surface of the trench 12. Subsequently, an Al₂O₃ film 15 about 20 Å thick is deposited on the oxynitride film 14 by ALD (Atomic Layer Deposition). By PDA (Post Deposition Anneal) at about 950° C. and about 30 minutes, an SiN film 16 is then deposited on the Al₂O₃ film 15 by LP-CVD (Low Pressure-Chemical Vapor Deposition). After that, a node electrode 17 made of a polysilicon film containing As is formed on the SiN film 16.

As shown in FIG. 5, the upper portion of the node electrode 17 is recessed by CDE (Chemical Dry Etching). Then, the SiN film 16, Al₂O₃ film 15, and oxynitride film 14 are peeled off only from the upper portion of the trench 12. In this manner, a trench capacitor 18 is formed in the trench 12.

Subsequently, as shown in FIG. 1, a collar insulating film 19 which is a TEOS film is selectively formed in the upper portion of the trench 12, thereby forming a collar structure in the upper portion of the trench 12. A connecting portion 20 is then formed in the upper portion of the trench 12. After that, a transistor 21 electrically connected to the capacitor 18 is formed on the silicon substrate 11 by a normal trench DRAM formation step.

In the first embodiment described above, the Al₂O₃ film 15 is sandwiched between the oxynitride film 14 and SiN film 16 containing nitrogen. Therefore, even when a high-temperature heating step for a DRAM is performed, diffusion of Al to the plate electrode 13 and node electrode 17 may be suppressed. Since the depletion ratios of the plate electrode 13 and node electrode 17 may be increased, a decrease in capacitance may be prevented, and a leakage current suppressing effect equivalent to that when an NO film is used may be obtained.

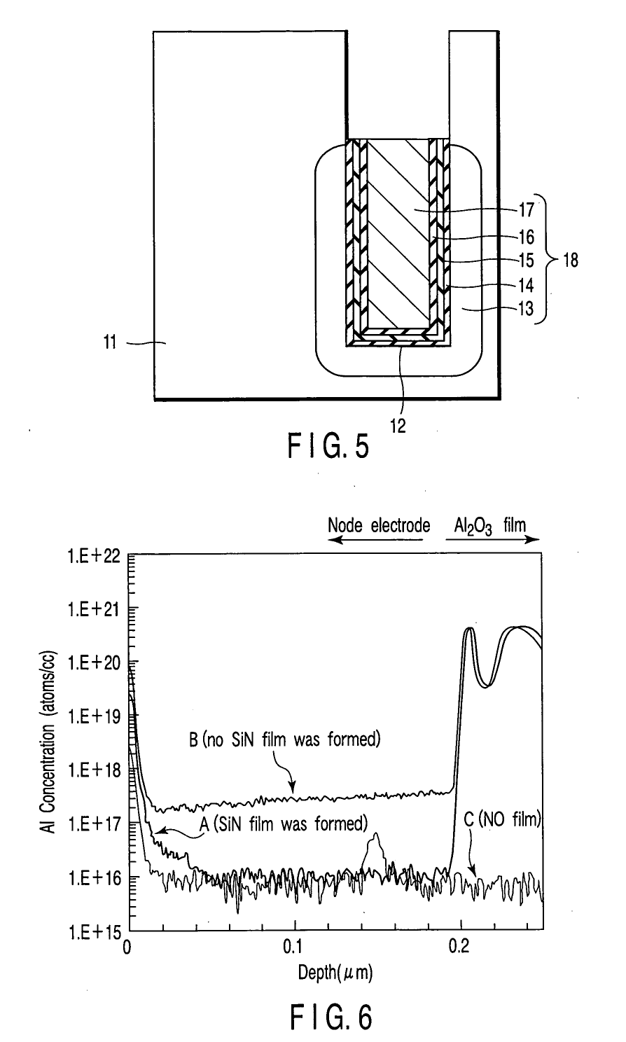

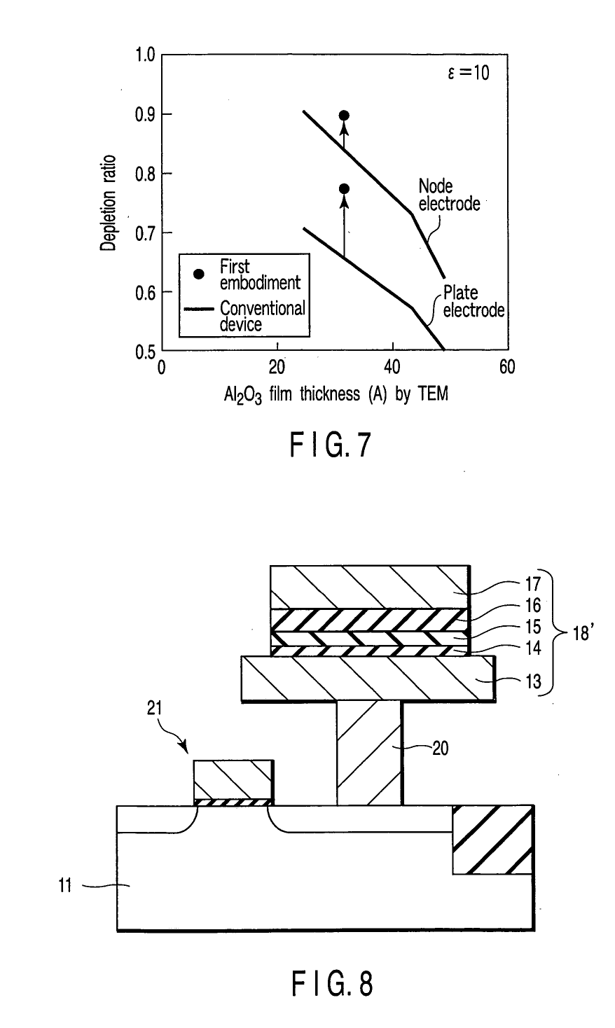

More specifically, as shown in FIG. 6, in the first embodiment (A) in which the SiN film 16 is formed between the Al₂O₃ film 15 and node electrode 17, Al diffusion toward the node electrode 17 may be suppressed, compared to a case (B) in which no SiN film is formed, to substantially the same extent as in a case (C) in which an NO film is used as a capacitor insulating film. Also, as shown in FIG. 7, the depletion ratios of the plate electrode 13 and node electrode 17 in the first embodiment are higher than in the conventional device.

Furthermore, as in the conventional device, the film thickness of an NO film used as a capacitor insulating film is about 50 Å. However, as in the first embodiment, the film thickness of the Al₂O₃ film 15 used as a capacitor insulating film may be 35 Å or less. In the first embodiment, therefore, a capacitor insulating film which is effectively thinner than an NO film may be formed while Al diffusion is suppressed.

Note that the first embodiment is not limited to the trench capacitor 18. For example, as shown in FIG. 8, the first embodiment is, of course, applicable to a stacked capacitor 18′ which is stacked on a silicon substrate 11. Although the first embodiment is very effective for the trench capacitor 18 having undergone a number of heating steps, the first embodiment is also effective for the stacked capacitor 18′ when heating steps are performed.

### Second Embodiment

The second embodiment is a modification of the first embodiment, in which nitrogen-containing films are omitted by causing at least one of the interface between an Al₂O₃ film and plate electrode and the interface between the Al₂O₃ film and a node electrode to contain nitrogen.

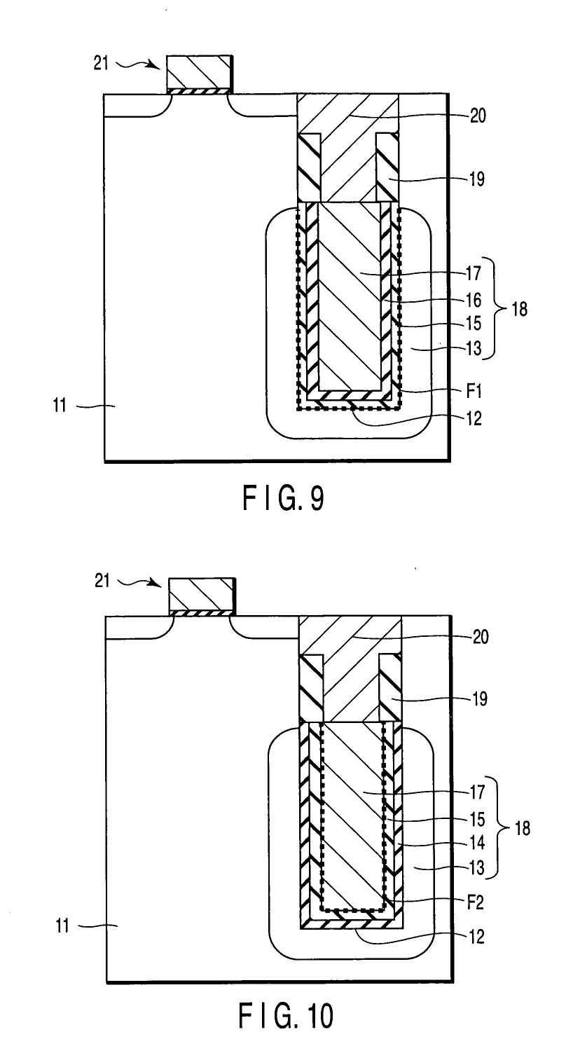

FIGS. 9 to 11 are sectional views showing a semiconductor device according to the second embodiment of the present invention. The structure of this semiconductor device according to the second embodiment will be described below.

As shown in FIGS. 9 to 11, the second embodiment differs from the first embodiment in that nitrogen-containing films (an oxynitride film 14 and SiN film 16) are omitted by causing at least one of an interface F1 between an Al₂O₃ film 15 and plate electrode 13 and an interface F2 between the Al₂O₃ film 15 and a node electrode 17 to contain nitrogen.

In the structure shown in FIG. 9, an oxynitride film 14 is omitted by causing the interface F1 between the Al₂O₃ film 15 and plate electrode 13 to contain nitrogen. An SiN film 16 is formed between the Al₂O₃ film 15 and node electrode 17.

In the structure shown in FIG. 10, an SiN film 16 is omitted by causing the interface F2 between the Al₂O₃ film 15 and node electrode 17 to contain nitrogen. An oxynitride film 14 is formed between the Al₂O₃ film 15 and plate electrode 13.

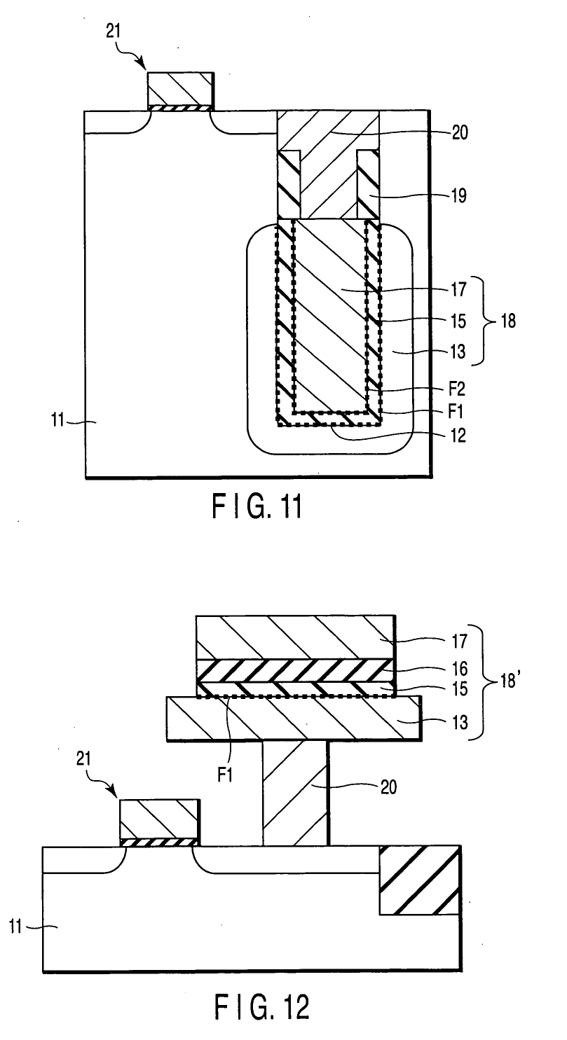

In the structure shown in FIG. 11, an oxynitride film 14 is omitted by causing the interface F1 between the Al₂O₃ film 15 and plate electrode 13 to contain nitrogen, and an SiN film 16 is omitted by causing the interface F2 between the Al₂O₃ film 15 and node electrode 17 to contain nitrogen.

In these structures, the content of nitrogen in the interfaces F1 and F2 is desirably 1% or more.

In the above second embodiment, the same effects as in the first embodiment may be obtained. In addition, the oxynitride film 14 and SiN film 16 may be omitted by causing at least one of the interface F1 between the Al₂O₃ film 15 and plate electrode 13 and the interface F2 between the Al₂O₃ film 15 and node electrode 17 to contain nitrogen. As a consequence, micropatterning may be performed without reducing the capacitance of the capacitor.

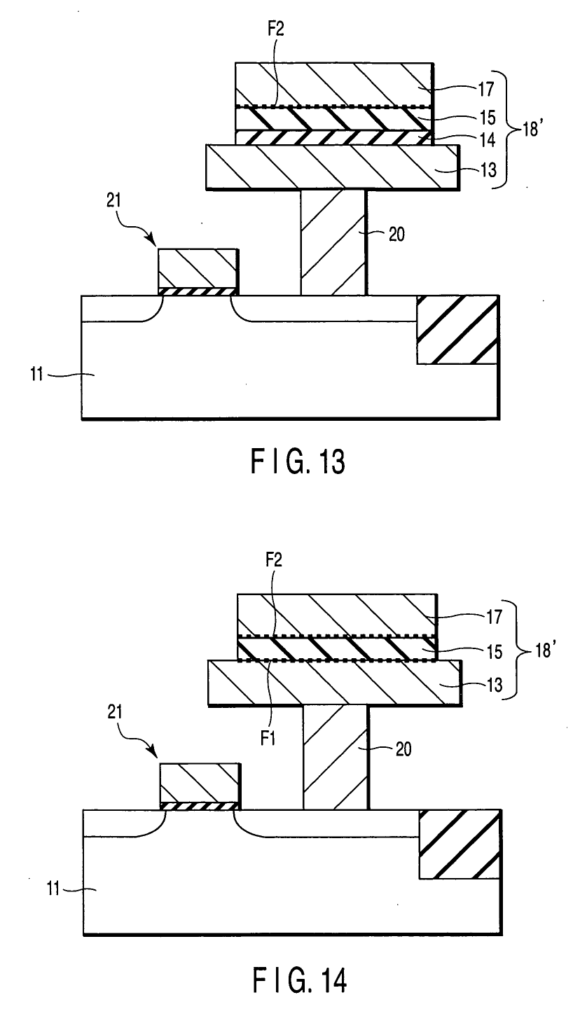

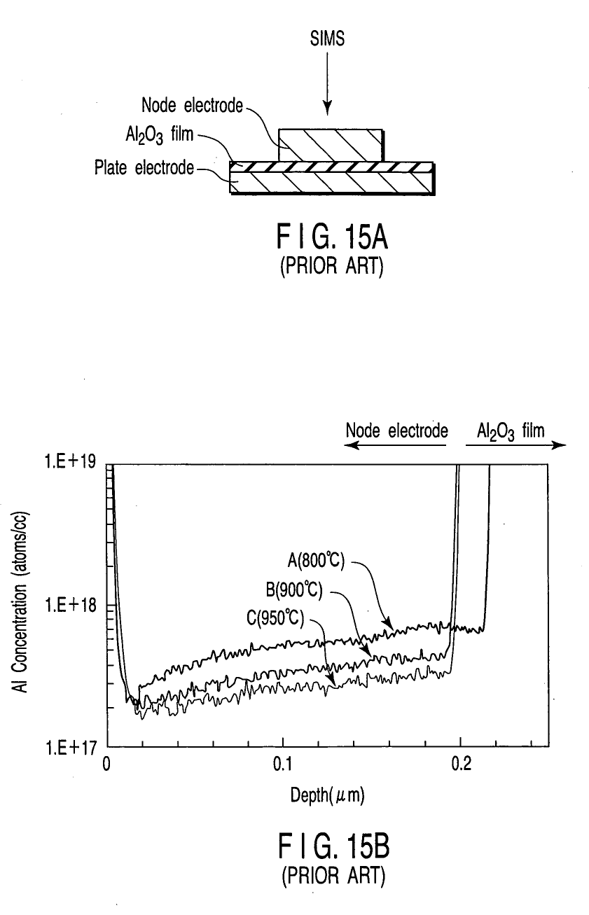

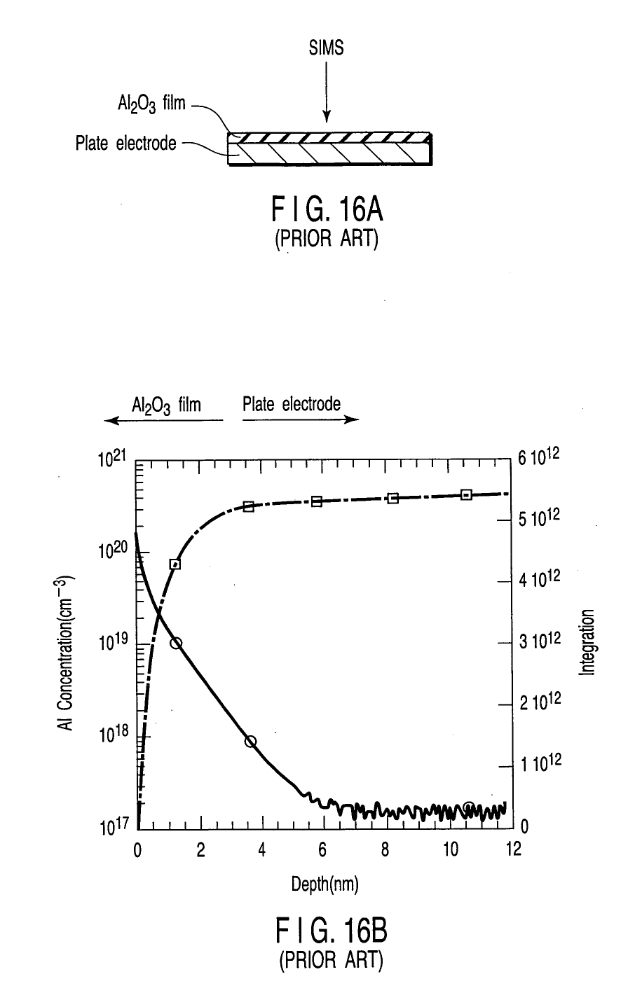

Note that the second embodiment is not limited to a trench capacitor 18. For example, as shown in FIGS. 12 to 14, the second embodiment is, of course, applicable to a stacked capacitor 18′ which is stacked on a silicon substrate 11. Although the second embodiment is very effective for the trench capacitor 18 having undergone a number of heating steps, the second embodiment is also effective for the stacked capacitor 18′ when heating steps are performed.

Note also that the present invention is not limited to the above embodiments, and may be variously modified, when practiced, without departing from the spirit and scope of the invention. For example, a plate electrode of a trench capacitor may also be formed in a trench by using polysilicon. Alternatively, it is also possible to form a trench in an interlayer dielectric film deposited on a silicon substrate, and form a capacitor in this trench.

Additional advantages and modifications will readily occur to those skilled in the art. Therefore, the invention in its broader aspects is not limited to the specific details and representative embodiments shown and described herein. Accordingly, various modifications may be made without departing from the spirit and scope of the general inventive concept as defined by the appended claims and their equivalents.

1. A semiconductor device comprising:
an upper electrode;
a lower electrode;
a capacitor insulating film formed between the upper and lower electrodes, and containing aluminum;
a first nitrogen-containing film formed between the capacitor insulating film and upper electrode, and containing nitrogen; and
a second nitrogen-containing film formed between the capacitor insulating film and lower electrode, and containing nitrogen,
wherein at least one of the first and second nitrogen-containing films contains not less than 1% of nitrogen.

2. A semiconductor device comprising:
an upper electrode;
a lower electrode; and
a capacitor insulating film formed between the upper and lower electrodes, containing aluminum, and having a first surface facing the upper electrode and a second surface facing the lower electrode,
wherein at least one of the first and second surfaces of the capacitor insulating film contains not less than 1% of nitrogen.

3. The device according to claim 1, wherein the first nitrogen-containing film is thicker than the capacitor insulating film.

4. The device according to claim 1, wherein a film thickness of the first nitrogen-containing film is 10 to 40 Å.

5. The device according to claim 1, wherein a film thickness of the first nitrogen-containing film is 15 to 30 Å.

6. The device according to claim 1, wherein the second nitrogen-containing film is thinner than the capacitor insulating film.

7. The device according to claim 1, wherein the second nitrogen-containing film is thinner than the first nitrogen-containing film.

8. The device according to claim 1, wherein a film thickness of the second nitrogen-containing film is not more than 15 Å.

9. The device according to claim 1, wherein a content of nitrogen in the second nitrogen-containing film increases near an interface between the second nitrogen-containing film and lower electrode.

10. The device according to claim 1, wherein a content of nitrogen in the second nitrogen-containing film increases near an interface between the second nitrogen-containing film and capacitor insulating film.

11. The device according to claim 1, wherein the first nitrogen-containing film is a silicon nitride film or an oxynitride film, and the second nitrogen-containing film is a silicon nitride film or an oxynitride film.

12. The device according to claim 1, wherein a film thickness of the capacitor insulating film is less than 40 Å.

13. The device according to claim 2, wherein a film thickness of the capacitor insulating film is less than 40 Å.

14. The device according to claim 1, wherein a film thickness of the capacitor insulating film is 1 to 25 Å.

15. The device according to claim 2, wherein a film thickness of the capacitor insulating film is 1 to 25 Å.

16. The device according to claim 1, wherein the capacitor insulating film is made of alumina.

17. The device according to claim 1, wherein a capacitor including the upper electrode, lower electrode, and capacitor insulating film is a trench capacitor.

18. The device according to claim 17, wherein the lower electrode is a diffusion layer in a semiconductor substrate.

19. The device according to claim 1, wherein a capacitor including the upper electrode, lower electrode, and capacitor insulating film is a stacked capacitor.

20. The device according to claim 1, wherein the first and second nitrogen-containing films prevent the aluminum from diffusing into the upper and lower electrodes.
